(19) United States
(12) Patent Application Publication
(10) Pub. No.: US 2006/0132183 A1
(43) Pub. Date: Jun. 22, 2006

(54) Semiconductor device

(76) Inventors: Dong-Jin Lim, Gyeonggi-do (KR); Sang-Seok Kang, Gyeonggi-do (KR); Byung-Heon Kwak, Gyeonggi-do (KR); Jae-Hoon Joo, Gyeonggi-do (KR); Chang-Hag Oh, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/312,953

(22) Filed: Dec. 19, 2005

(30) Foreign Application Priority Data
Dec. 22, 2004 (KR) 2004-110623

(51) Int. Cl. H03K 19/094

(52) U.S. Cl. 326/83

(57) ABSTRACT

A semiconductor device that performs stable circuit operations is provided. The device includes: a pull-up driver for pulling up a first node in response to first states of input and control signals; a pull-down driver for pulling down a second node in response to a second state of the input signal; at least one fuse connected between the first node and the second node; a latch for generating an output signal to maintain the state of the second node; and a controller for generating the control signal that is maintained in a first state when the input signal is in the second state, and maintained in the first state and then transitioned to the second state after a predetermined delay time when the input signal is transitioned to the first state. In this construction, even if the fuse is incompletely cut during a process of cutting the fuse, the pull-up driver or the pull-down driver is turned off, thus preventing unnecessary current flow in advance.

### CROSS-REFERENCE TO RELATED APPLICATION

This application claims the benefit of Korean Patent Application No. 10-2004-0110623, filed Dec. 22, 2004, the disclosure of which is hereby incorporated herein by reference in its entirety.

### BACKGROUND OF THE INVENTION

1. Field of the Invention

This disclosure relates to a semiconductor device and, more particularly, to a semiconductor device including a mode switching circuit, which performs stable circuit operations.

2. Description of the Related Art

In general, a semiconductor memory device, such as a synchronous dynamic random access memory (SDRAM), includes a redundancy circuit to repair defective cells. The redundancy circuit makes use of fuses. In order to repair the defective cells in a wafer operation, fuses corresponding to the defective cells are cut using laser beams. In this case, the fuses may not be completely cut so that an unnecessary current path may be formed to cause defects. Additionally, the fuses are used for various mode switching circuits. However, when the fuses are incompletely cut, mode switching is not fulfilled or unnecessary current flows, causing noise. As a result, characteristics of the semiconductor device may be degraded.

FIG. 1 is a schematic diagram of a conventional mode switching circuit 100 having a fuse circuit. The mode switching circuit 100 includes a PMOS transistor MP1, an NMOS transistor MN1, a fuse F, an NMOS transistor MN2, and inverters I1, I2 and I3. The PMOS transistor MP1 constitutes a pull-up driver, the NMOS transistor MN1 constitutes a pull-down driver, and the NMOS transistor MN2 and the inverter I2 constitute a latch. In FIG. 1, a power-up signal pVCCH is maintained at a low level for a first predetermined period of time (region A) and then maintained at a high level for a second predetermined period of time (region B) after a power supply voltage VCC is applied.

The operations of the mode switching circuit 100 shown in FIG. 1 will now be described to facilitate the understanding of conventional problems. For example, when the power-up signal pVCCH is at a low level, the NMOS transistor MN1 pulls a node B to a low level. In this case, the latch serves to keep the node B at the low level. Thereafter, when the power-up signal pVCCH transitions to a high level, the PMOS transistor MP1 pulls the node B, making a low-to-high transition. Thus, as long as the fuse F is not cut, an output signal pOUT transitions to a high level.

Alternatively, when the fuse F is cut in a semiconductor fabrication process for mode switching or other purposes, even if the power-up signal pVCCH is maintained at a high level, the node B remains at a low level. Thus, the output signal pOUT is output at a low level.

However, in some cases, even if the fuse F is cut in the wafer operation, the fuse F may not be completely cut but slightly connected. Thus, unnecessary current may flow along a path as illustrated by a dotted line, causing unnecessary power consumption. In addition, the output signal pOUT may be undesirably output at a high level, the mode switching is not performed.

### SUMMARY OF THE INVENTION

An embodiment of the invention provides a semiconductor device including a mode switching circuit, which performs stable operations after a process of cutting fuses.

Another embodiment of the invention provides a semiconductor device including a mode switching circuit, which enables stable mode switching even if fuses are incompletely cut.

In one aspect, the invention is directed to a semiconductor device including: a pull-up driver for pulling up a first node in response to first states of input and control signals; a pull-down driver for pulling down a second node in response to a second state of the input signal; at least one fuse connected between the first node and the second node; a latch for generating an output signal to maintain the state of the second node; and a controller for generating the control signal that is maintained in a first state when the input signal is in the second state, and maintained in the first state and then transitioned to the second state after a predetermined delay time when the input signal is transitioned to the first state.

The pull-up driver may include first and second PMOS transistors that are serially connected between a power supply voltage and the first node, and each of the first and second PMOS transistors may have a gate to which the control and input signals are applied. The pull-down driver may include a first NMOS transistor that is connected between the second node and a ground voltage and has a gate to which the input signal is applied. The latch may include an inverter for inverting a signal of the second node to generate the output signal; a third PMOS transistor for keeping the second node in the second state in response to the first state of the output signal; and a second NMOS transistor for keeping the second node in the first state in response to the second state of the output signal.

In one embodiment, the controller may include a delay unit for delaying the input signal to generate a delayed input signal; and a control unit for generating the control signal being in the first state when both the delayed input signal and the output signal are in the second state. The delay unit may include even-numbered inverters that are cascade-connected. Also, the control unit may include a NAND gate that performs an NAND operation on the delayed input signal and the output signal and generates the control signal.

In another embodiment, the controller may include a delay unit for delaying the input signal to generate a delayed input signal; and a control unit for generating the control signal being in the first state when the input signal is in the second state and for generating the control signal being in the first state in the case that both the delayed input signal and the output signal are in the second state when the input signal is in the first state. The delay unit may include even-numbered inverters that are cascade-connected. Also, the control unit may include an AND gate for performing an AND operation on the delayed input signal and the output signal; and a NOR gate for performing a NOR operation on the input signal and an output signal of the AND gate to generate the control signal.

In another aspect, the invention is directed to a semiconductor device including a pull-up driver for pulling up a first node in response to a first state of an input signal; a pull-down driver for pulling down a second node in response to second states of the input signal and a control signal; at least one fuse connected between the first node and the second node; a latch for generating an output signal to maintain the state of the first node; and a controller for generating the control signal that is maintained in the second state when the input signal is in the first state, and maintained in the second state and then transitioned to the first state when the input signal is transitioned to the second state.

The pull-up driver may include a first PMOS transistor that is connected between a power supply voltage and the first node and has a gate to which the input signal is applied. The pull-down driver may include first and second NMOS transistors that are serially connected between the second node and a ground voltage, and each of the first and second NMOS transistors may have a gate to which the input and control signals are applied. The latch may include an inverter for inverting a signal of the first node to generate the output signal; a second PMOS transistor for keeping the first node in the second state in response to the output signal of the inverter; and a third NMOS transistor for keeping the first node in the first state in response to the output signal of the inverter.

The controller may include a delay unit for delaying the input signal for a predetermined delay time to generate a delayed input signal; and a control unit for generating the control signal being in the second state when both the delayed input signal and the output signal are in the first state. The delay unit may include even-numbered inverters that are cascade-connected. Also, the control unit may include a NOR gate that performs a NOR operation on the delayed input signal and the output signal to generate the control signal.

The first state may be a low level, and the second state may be a high level.

### BRIEF DESCRIPTION OF THE DRAWINGS

The foregoing and other objects, features and advantages of the invention will be apparent from the more particular description of embodiments, as illustrated in the accompanying drawings. The drawings are not necessarily to scale, emphasis instead being placed upon illustrating the principles of embodiments of the invention.

FIG. 1 is a schematic diagram of a conventional mode switching circuit having a fuse circuit.

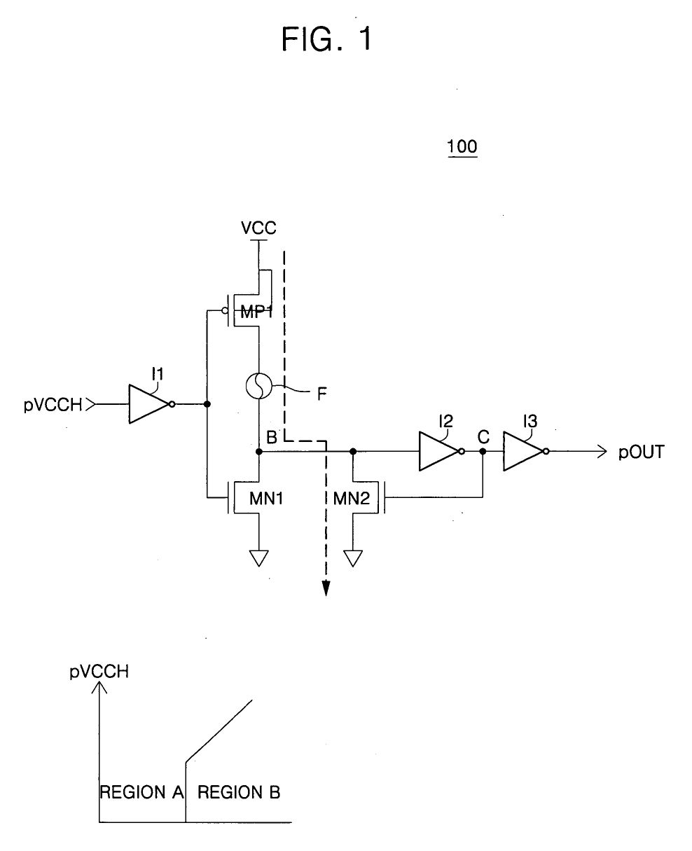

FIG. 2 is a schematic diagram of an embodiment of a mode switching circuit having a fuse circuit.

FIG. 3 is a schematic diagram of another embodiment of a mode switching circuit having a fuse circuit.

FIG. 4 is a schematic diagram of another embodiment of a mode switching circuit having a fuse circuit.

### DETAILED DESCRIPTION

Embodiments of a semiconductor device including a mode switching circuit that performs stable operations will now be described more fully hereinafter with reference to the accompanying drawings, in which exemplary embodiments of the invention are shown.

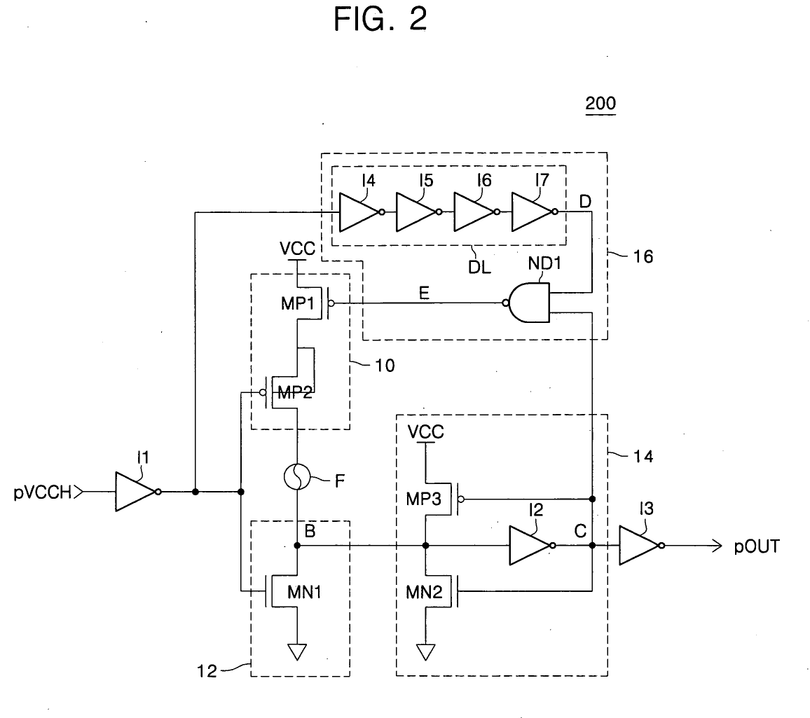

FIG. 2 is a schematic diagram of a mode switching circuit 200 according to an exemplary embodiment of the present invention. Referring to FIG. 2, the mode switching circuit 200 includes a pull-up driver 10, a pull-down driver 12, a fuse F, a latch 14, a controller 16, and an inverter I3.

The pull-up driver 10 includes PMOS transistors MP1 and MP2, the pull-down driver 12 includes an NMOS transistor MN1, the latch 14 includes a PMOS transistor MP3, an NMOS transistor MN2, and an inverter I3, and the controller 16 includes a NAND gate ND1 and a delay unit DL having four cascade-connected inverters I4-I7.

Functions of the respective components shown in FIG. 2 will now be described.

While a power-up signal pVCCH is at a low level, the pull-up driver 10 is disabled, and the pull-down driver 12 keeps a node B at a low level. The first PMOS transistor MP1 is turned on, and the second PMOS transistor MP2 is turned off. In other words, with a predetermined delay time caused by the delay unit DL, the NAND gate ND1 outputs a low level signal due to a high-level signal of a node D and a high-level signal of a node C, so that the first PMOS transistor MP1 is turned on.

When the power-up signal pVCCH transitions to a high level, the second PMOS transistor MP2 also is turned on so that the node B transitions to a high level. The inverter I2 and the third PMOS transistor MP3 serve to latch a signal of the high level of the node B. With a predetermined delay time, the NAND gate ND1 outputs a high level signal and the first PMOS transistor MP1 is turned off.

Accordingly, even if the fuse F is incompletely cut and current may flow through the cut fuse, the first PMOS transistor MP1 is turned off due to the delay unit DL and the NAND gate ND1. Thus, it is possible to prevent the problems such as mode switching not being successfully carried out and excessive current flows. As used herein, a substantially cut fuse refers to a completely cut fuse and a fuse that was attempted to be cut, but remains incompletely cut. An intact fuse refers to a fuse that was not attempted to be cut.

When the power-up signal pVCCH is at a low level, the first NMOS transistor MN1 is turned on so that the node B remains at a low level, and the inverter I2 and the NMOS transistor MN2 serve to latch a signal of the low level of the node B. The pull-down driver 12 has the same construction and performs the same operation as the conventional driver. That is, this embodiment is characterized by having the pull-up driver 10 that is disabled after its enabling so as to overcome conventional drawbacks.

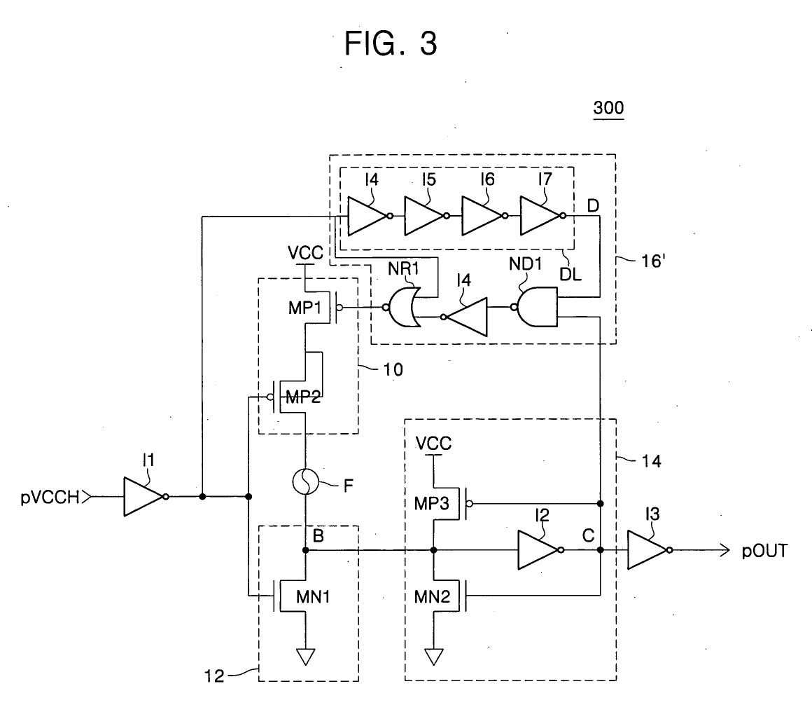

FIG. 3 is a schematic diagram of another embodiment of a mode switching circuit 300. The mode switching circuit 300 has the same construction as the mode switching circuit 200 shown in FIG. 2 except that the controller 16 is replaced by a controller 16′.

The controller 16′ includes a delay unit DL, a NAND gate ND1, an inverter I4, and a NOR gate NR1.

In this embodiment, the controller 16′ additionally includes a logic circuit such that turn-on time and turn-off time of a first PMOS transistor MP1 are differently set. That is, when a power-up signal pVCCH transitions to a low level, the first PMOS transistor MP1 is turned on earlier than the first PMOS transistor MP1 of FIG. 2. In other words, the NOR gate NR1 receives a high-level signal irrespective of a delay unit 15 and outputs a low-level signal before the high signal propagates through the delay unit DL. Thus, after a delay time caused by the NOR gate NR1, the first PMOS transistor MP1 is turned on, while a second PMOS transistor MP2 remains turned off.

Thereafter, when the power-up signal pVCCH transitions to a high level, the pull-up driver 10 is enabled, and a node B is maintained at a high level. After a lapse of a predetermined period of time, a low-level signal of a node C is input to the NAND gate ND1. Since the NOR gate NR1 receives only low-level signals from two input nodes, it outputs a high-level signal. Thus, the first PMOS transistor MP1 is turned off. Since the operations of other components are the same as those in FIG. 2, descriptions thereof will not be repeated here.

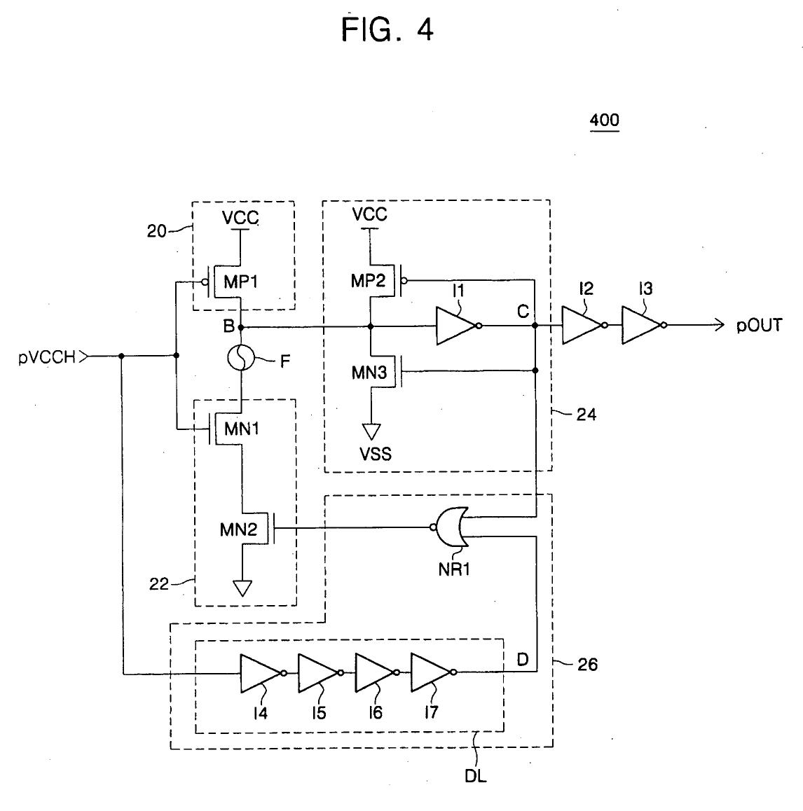

FIG. 4 is a schematic diagram of another embodiment of a mode switching circuit 400. Referring to FIG. 4, the mode switching circuit 400 includes a pull-up driver 20, a pull-down driver 22, a fuse F, a latch 24, a controller 26, and inverters I2 and I3.

In FIG. 4, the pull-up driver 20 includes a first PMOS transistor MP1, the pull-down driver 22 includes first and second NMOS transistors MN1 and MN2, the latch 24 includes a PMOS transistor MP2, an NMOS transistor MN2, and an inverter I1, and the controller 26 includes a NOR gate NR1 and four cascade-connected inverters I4 through I7 forming a delay unit DL.

Functions of the respective components shown in FIG. 4 will now be described.

While a power-up signal pVCCH is at a low level, the pull-up driver 20 is activated, and a node B is maintained at a high level. Also, the inverter I1 and the second PMOS transistor MP2 serve to keep the node C at the low level. The pull-down driver 22 includes the first NMOS transistor MN1 and the second NMOS transistor MN2. When the power-up signal pVCCH transitions to a high level, the pull-down driver 22 is activated, thus the node B transitions to a low level. However, after a lapse of predetermined period of time, the second NMOS transistor MN2 is turned off. In this case, the inverter I1 and a third NMOS transistor MN3 serve to latch a signal of the low level of the node B.

Accordingly, after the process of cutting the fuse F, even if the fuse F is incompletely cut and remains slightly connected, the second NMOS transistor MN2 is turned off due to the delay unit DL and the NOR gate NR1. Thus, mode switching is successfully carried out and an excessive current flow is prevented. That is, this embodiment is characterized by having a pull-down driver that is disabled after its enabling so as to overcome conventional drawbacks.

In a mode switching circuit, a redundancy circuit, or other circuits that includes fuses, the fuses may be cut using laser beams in a semiconductor fabrication process. Since each of the fuses may be incompletely cut, unnecessary power consumption arises or mode switching is failed, thus deteriorating the reliability of the circuits. However, as described above, after a pull-up or pull-down driver is activated, it is disabled after a predetermined delay time. Consequently, even if the fuse is incompletely cut, waste of current is prevented, and the mode switching is successfully carried out.

Although means for disabling a pull up and a pull down driver have been described using NMOS and PMOS transistors, other transistor types, other switching devices, or other devices that may vary the current flowing through them may be used. Furthermore, although a delay unit has been described as including inverters, a delay unit may be any circuit that delays the propagation of a transition of a signal. In addition, although logic for disabling a driver has been described as including a NAND gate or a NOR gate, such logic may include any logic that disables the driver after a desired delay time.

Preferred embodiments have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A semiconductor device comprising:
a first driver for providing a first voltage to a first node in response to an input signal and a control signal both being in a first state;
a second driver for providing a second voltage to a second node in response to the input signal being in a second state;
a fuse connected between the first node and the second node;
a latch for generating an output signal to maintain the state of voltage at the second node; and
a controller for generating the control signal in the first state when the input signal is in the second state, and transitioning to the second state after a predetermined delay time when the input signal is transitioned to the first state.

2. The device according to claim 1, wherein the first driver is a pull up driver.

3. The device according to claim 2, wherein the second driver is a pull down driver.

4. The device according to claim 1, wherein the input signal is an inverted power-up signal and is maintained in the second state for a predetermined period of time while a power supply voltage is applied and then transitioned to the first state.

5. The device according to claim 3, wherein the pull-up driver includes first and second PMOS transistors serially connected between the power supply voltage and the first node, and each of the first and second PMOS transistors having a gate, the control signal and the input signal applied to the gate of the first PMOS transistor and the second PMOS transistor, respectively.

6. The device according to claim 5, wherein the pull-down driver includes a first NMOS transistor connected between the second node and a ground voltage and has a gate to which the input signal is applied.

7. The device according to claim 6, wherein the latch includes:
an inverter for inverting a signal of the second node to generate the output signal;
a third PMOS transistor for maintaining the second voltage at the second node in response the output signal being in the first state; and
a second NMOS transistor for maintaining the first voltage at the second node in response to the output signal being in the second state.

8. The device according to claim 4, wherein the controller includes:
a delay unit for delaying the input signal to generate a delayed input signal; and
a control unit for generating the control signal in the first state when both the delayed input signal and the output signal are in the second state.

9. The device according to claim 8, wherein the delay unit includes an even number of cascading inverters.

10. The device according to claim 8, wherein the control unit includes a NAND gate for performing a NAND operation on the delayed input signal and the output signal and for generating the control signal.

11. The device according to claim 4, wherein the controller includes:
a delay unit for delaying the input signal to generate a delayed input signal; and
a control unit for generating the control signal in the first state when the input signal is in the second state and generating the control signal in the first state when both the delayed input signal and the output signal are in the second state while the input signal is in the first state.

12. The device according to claim 11, wherein the delay unit includes an even number of cascading inverters.

13. The device according to claim 11, wherein the control unit includes:
an AND gate for performing an AND operation on the delayed input signal and the output signal; and
a NOR gate for performing a NOR operation on the input signal and an output signal of the AND gate to generate the control signal.

14. The device according to claim 3, wherein the first state is a low level and the second state is a high level.

15. The device according to claim 1, wherein the first driver is a pull down driver.

16. The device according to claim 15, wherein the second driver is a pull up driver.

17. The device according to claim 16, wherein the pull-down driver includes first and second NMOS transistors serially connected between the first node and the ground voltage, and each of the first and second NMOS transistors having a gate, the input signal and the control signal applied to the first NMOS transistor and the second NMOS transistor, respectively.

18. The device according to claim 17, wherein the pull-up driver includes a first PMOS transistor connected between the power supply voltage and the second node and has a gate to which the input signal is applied.

19. The device according to claim 18, wherein the latch includes:
an inverter for inverting a signal of the second node to generate the output signal;
a second PMOS transistor for maintaining the first voltage at the second node in response to the output signal of the inverter; and
a third NMOS transistor for maintaining the second voltage at the second node in response to the output signal of the inverter.

20. The device according to claim 19, wherein the controller includes:
a delay unit for delaying the input signal for a predetermined delay time to generate a delayed input signal; and
a control unit for generating the control signal in the first state when both the delayed input signal and the output signal are in the second state.

21. The device according to claim 20, wherein the delay unit includes an even number of cascading inverters.

22. The device according to claim 21, wherein the control unit includes a NOR gate for performing a NOR operation on the delayed input signal and the output signal for generating the control signal.

23. The device according to claim 16, wherein the first state is a high level and the second state is a low level.
